(19) United States
(12) Patent Application Publication
(10) Pub. No.: US 2025/0089258 A1
(43) Pub. Date: Mar. 13, 2025

(54) MANUFACTURING METHOD OF MEMORY DEVICE AND MANUFACTURING METHOD OF TUNGSTEN LAYER

(71) Applicant: MACRONIX International Co., Ltd., Hsinchu (TW)

(72) Inventors: Meng-Hsun Hsieh, New Taipei City (TW); Tuung Luoh, Taipei City (TW); Kuang-Wei Chen, Hsinchu City (TW); Kuang-Chao Chen, Taipei City (TW); Ta-Hung Yang, Miaoli County (TW)

(73) Assignee: MACRONIX International Co., Ltd., Hsinchu (TW)

(21) Appl. No.: 18/465,166

(22) Filed: Sep. 12, 2023

(51) Int. Cl. H10B 43/35; H10B 41/27; H10B 41/35; H10B 43/27

(52) U.S. Cl. CPC H10B 43/35; H10B 41/27; H10B 41/35; H10B 43/27

(57) ABSTRACT

A manufacturing method of a memory device may be applied to a three-dimensional NAND memory device with high capacity and high performance. In a manufacturing process of the three-dimensional NAND memory device, a material of a control gate (word line) is tungsten. The forming method of a tungsten layer includes nucleation and bulk formation performed. In at least one of the nucleation and the bulk formation, hydrogen flow is between 1000 and 20000 sccm. At least one time of soak with nitrogen may also be performed after the nucleation. A tungsten grain size in the tungsten layer is 70 nm or more.

### BACKGROUND

### Technical Field

The disclosure relates to a manufacturing method of a semiconductor device, and in particular to a manufacturing method of a memory device and a manufacturing method of a tungsten layer.

### Description of Related Art

As technology advances with each passing day, progress in an electronic device has increased a need for greater storage capacity. In order to meet a demand of high storage density (high storage density), a size of a memory device has become smaller and more densely. Therefore, a type of the memory device has changed from a planar gate structure of a two-dimensional memory device (2D memory device) to a three-dimensional memory device (3D memory device) with a vertical channel (VC) structure.

For the three-dimensional NAND (3D NAND) memory device, low fluorine tungsten (LFW) is used as a material of a control gate (word line), which may improve an effect of a drive device.

### SUMMARY

The disclosure provides a manufacturing method of a memory device, which may manufacture low fluorine tungsten (LFW) with a large grain size, low resistivity, and low fluorine concentration as a material of a word line (control gate). The manufacturing method may reduce the control gate driving voltage and a risk of fluorine that is damage to a high-k dielectric constant material and a floating gate, narrow a threshold voltage (Vth) distribution, and improve reliability.

The disclosure provides a manufacturing method of a tungsten layer, which may manufacture low fluorine tungsten (LFW) with a large grain size, low resistivity, and low fluorine concentration.

The disclosure provides a manufacturing method of a memory device, including the following steps. A substrate is provided. A stacked structure is formed on the substrate, where the stacked structure includes a plurality of first material layers and a plurality of second material layers alternately stacked on each other. The stacked structure is patterned to form a first opening in the stacked structure. A charge storage structure is formed on a sidewall of the first opening. A channel layer is formed on the charge storage structure. The plurality of second material layers are removed to form a plurality of second openings. A tungsten layer is formed in the plurality of second openings, where the tungsten layer formed includes nucleation and bulk formation performed after the nucleation. A nucleation precursor in the nucleation includes tungsten halide, hydrogen, and a reducing agent. A bulk precursor in the bulk formation includes tungsten halide, hydrogen, and a reducing agent. In at least one of the nucleation and the bulk formation, hydrogen flow is between 1000 and 20000 sccm.

In an embodiment of the disclosure, after nucleation, at least one time of soak with at least one of nitrogen, hydrogen, deuterium and ammonia after the nucleation is further performed.

In an embodiment of the disclosure, a plurality of times of bulk formation performed are further included.

In an embodiment of the disclosure, 3 times of bulk formation performed are included.

In an embodiment of the disclosure, 2 times of soak performed are included after nucleation.

In an embodiment of the disclosure, a barrier layer formed is further comprised before tungsten layer is formed in the plurality of second openings.

In an embodiment of the disclosure, in nucleation, hydrogen flow is 4000 sccm or more.

In an embodiment of the disclosure, in bulk formation, hydrogen flow is 5000 sccm or more.

In an embodiment of the disclosure, in soak, nitrogen flow is between 100 and 6000 sccm.

The disclosure provides a manufacturing method of a tungsten layer, including nucleation and bulk formation performed. A nucleation precursor in the nucleation including tungsten halide, hydrogen, and a reducing agent. A bulk precursor in the bulk formation including tungsten halide, hydrogen, and a reducing agent. In at least one of the nucleation and the bulk formation, hydrogen flow is between 1000 and 20000 sccm, and the tungsten grain size in the tungsten layer formed is 70 nm or more.

In an embodiment of the disclosure, at least one time of soak with at least one of nitrogen, hydrogen, deuterium and ammonia after the nucleation is performed after nucleation.

In an embodiment of the disclosure, a plurality of times of bulk formation performed are further included.

In an embodiment of the disclosure, 3 times of bulk formation performed are included.

In an embodiment of the disclosure, 2 times of soak performed are included after nucleation.

In an embodiment of the disclosure, in the nucleation, hydrogen flow is 4000 sccm or more.

In an embodiment of the disclosure, in bulk formation, hydrogen flow is 5000 sccm or more.

In an embodiment of the disclosure, in soak, nitrogen flow is between 100 and 6000 sccm.

In a plurality of embodiments of the disclosure, the hydrogen flow increased in the nucleation and the bulk formation and the total nitrogen soak flow reduced in the soak are both beneficial to obtain the large tungsten grain size. In the tungsten layer formed, as the tungsten grain size becomes larger, the fluorine content in the tungsten layer decreases. The tungsten grain size in the tungsten layer is larger and has fewer grain boundaries, which reduces the resistivity of tungsten and impurity (fluorine) that is easily to damage a high-k dielectric constant material and a floating gate, narrows the threshold voltage (Vth) distribution, and improves reliability of the memory device.

### BRIEF DESCRIPTION OF THE DRAWINGS

FIGS. 1A to 1E are schematic cross-sectional views of a manufacturing method of a three-dimensional memory device (3D memory device) according to an embodiment of the disclosure.

FIG. 2 is a flowchart of a manufacturing method of a tungsten layer according to an embodiment of the disclosure.

FIG. 3 is a graph illustrating a relationship between hydrogen flow and a tungsten grain size according to an embodiment of the disclosure.

FIG. 4 is a graph illustrating a relationship between a tungsten grain size and resistivity according to an embodiment of the disclosure.

### DESCRIPTION OF THE EMBODIMENTS

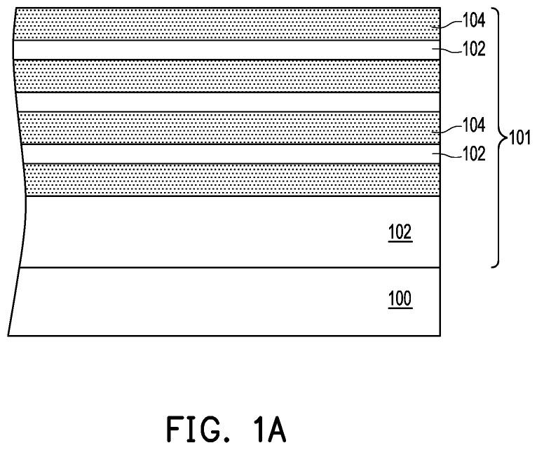

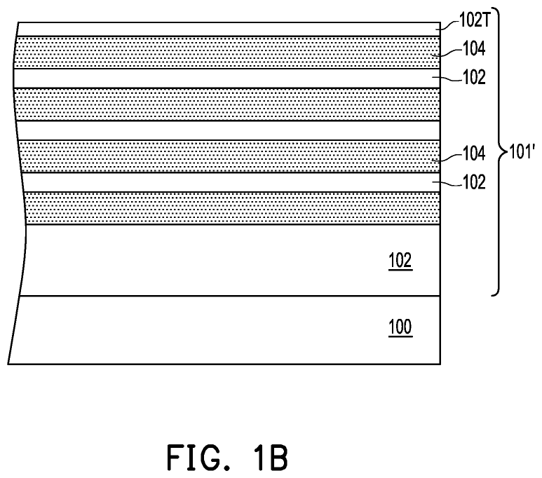

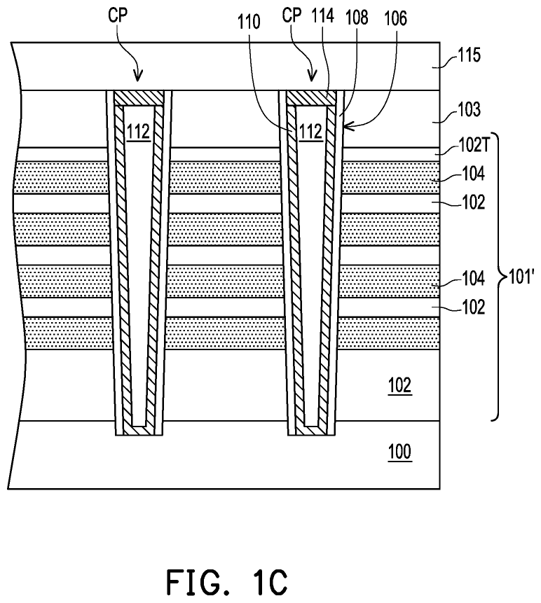

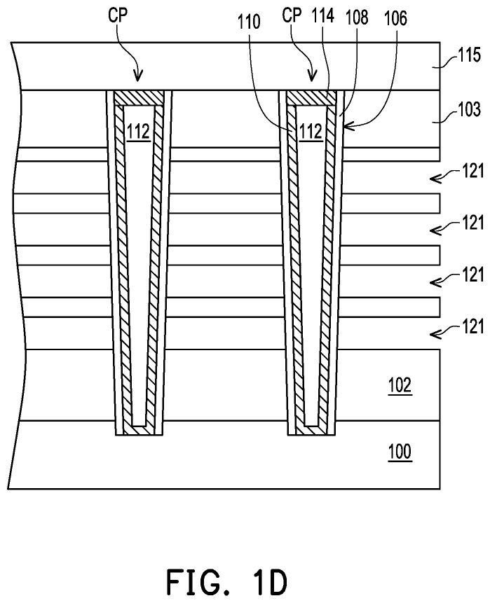

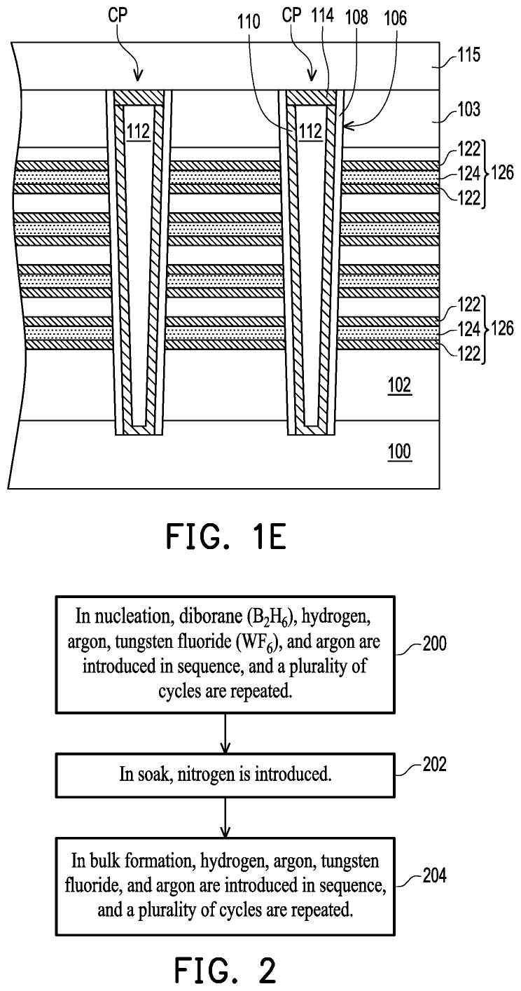

The disclosure provides a manufacturing method of a memory device and a manufacturing method of a tungsten layer, which may be applied to a three-dimensional NAND memory device with high capacity and high performance. FIGS. 1A to 1E are schematic cross-sectional views of a manufacturing method of a three-dimensional memory device (3D memory device) according to an embodiment of the disclosure.

Referring to FIG. 1A, a substrate 100 is provided. The substrate 100 may be a semiconductor substrate, for example, a silicon-containing substrate. In an embodiment, according to a design requirement, a doped region may be formed in the substrate 100. A device layer (not shown) and a metal interconnection structure (not shown) may be formed on the substrate 100. The device layer may include an active device or a passive device. The active device is, for example, a transistor, a diode, etc. The passive device is, for example, a capacitor, an inductor, etc. The metal interconnection structure may include a dielectric layer, a plug, a wire, etc.

Referring to FIG. 1A, a stacked structure 101 is formed on the substrate 100. The stacked structure 101 includes a plurality of first material layers 102 and a plurality of second material layers 104 alternately stacked. The first material layer 102 may be an insulating layer, for example, silicon oxide. The second material layer 104 may be an insulating layer (such as silicon nitride) or a conductor layer (such as doped polysilicon). In an embodiment, a material of a first material layer 102 includes silicon oxide, and a material of a second material layer 104 includes silicon nitride. In another embodiment, a material of a first material layer 102 includes silicon oxide, and a material of a second material layer 104 includes doped polysilicon. In this embodiment, a bottommost layer of the stacked structure 101 is the first material layer 102, and a topmost layer is the second material layer 104, but the disclosure is not limited thereto. In addition, in this embodiment, 4 layers of the second material layer 104 and 4 layers of the first material layer 102 are used for explanation. However, the disclosure is not limited thereto.

Next, referring to FIG. 1B, an insulating layer 102T is formed on the stacked structure 101. A material of the insulating layer 102T is different from a material of the second material layer 104. The material of the insulating layer 102T is the same as a material of the first material layer 104, for example, silicon oxide. The insulating layer 102T and the stacked structure 101 may be collectively referred to as a stacked structure 101′.

Afterwards, referring to FIG. 1C, the insulating layer 102T, the second material layer 104, the first material layer 102, and a support structure 98 of the stacked structure 101′ are patterned so as to form one or a plurality of openings 106 passing through the stacked structure 101′. In an embodiment, an opening 106 may have a slightly sloped sidewall. In an embodiment, an opening 106 may have a substantially vertical sidewall (not shown). In an embodiment, an opening 106 is also called a vertical channel (VC) hole. Vertical channel pillars (CP) are then formed in the openings 106. The vertical channel pillars (CP) may be formed by the methods described below, but not limited thereto.

Referring to FIG. 1C, a charge storage structure 108 is formed on the sidewall of the opening 106. The charge storage structure 108 is in contact with the first material layer 102 and the second material layer 104. A material of the charge storage structure 108 is, for example, a composite layer of oxide/nitride/oxide (ONO). In an embodiment, a charge storage structure 108 is formed on a sidewall of an opening 106 in a form of a spacer, and a bottom surface of the opening 106 is exposed.

Then, a channel layer 110 is formed on the charge storage structure 108. A material of the channel layer 110 includes, for example, polysilicon. In an embodiment, a channel layer 110 covers a charge storage structure 108 on a sidewall of an opening 106 and covers a bottom surface of an opening 106. Next, an insulating pillar 112 is formed at a lower portion of the opening 106. In an embodiment, a material of an insulating pillar 112 includes, for example, silicon oxide. Afterwards, a conductor plug 114 is formed on an upper portion of the opening 106, and the conductor plug 114 is in contact with the channel layer 110. In an embodiment, a material of a conductor plug 114 includes, for example, doped polysilicon. The channel layer 110 and the conductor plug 114 may be collectively referred to as the vertical channel pillar (CP). The charge storage structure 108 surrounds a vertical outer surface of the vertical channel pillar (CP). Next, an insulating cap layer 115 is formed on the stacked structure 101′. A material of the insulating cap layer 115 includes, for example, silicon oxide.

Referring to FIG. 1D, a selective etching process is performed to remove the second material layer 104 so as to form a plurality of openings 121. The opening 121 exposes part of the charge storage structure 108, the first material layer 102, and the insulating layer 102T. The selective etching process may be an isotropic etching process, for example a wet etching process. An etchant used in the wet etching process is, for example, hot phosphoric acid.

Referring to FIG. 1E, a conductor layer is formed in the opening 121. The conductor layer includes, for example, a barrier layer 122 and a metal layer 124. In an embodiment, a material of a barrier layer 122 includes aluminum oxide (Al₂O₃), titanium (Ti), titanium nitride (TiN), tantalum (Ta), tantalum nitride (TaN) or a combination thereof, and a material of a metal layer 124 is tungsten (W). The conductor layer in the opening 121 serves as a gate layer 126.

Next, a manufacturing method of the metal layer 124 (tungsten layer) of the disclosure is described. The manufacturing method of the metal layer 124 (tungsten layer) includes nucleation, soak, and bulk formation performed.

For the nucleation, if a nucleation size of tungsten is larger, a tungsten bulk has a beneficial to form a large grain size. A nucleation precursor in the nucleation includes tungsten halide (such as tungsten fluoride), hydrogen (or deuterium), and a reducing agent. The reducing agent is, for example, silane, borane, etc. In the nucleation, for example, inert gas including argon, helium, nitrogen, etc. may be added.

In an embodiment, when a reducing agent flow is less than 2000 sccm, hydrogen (or deuterium) flow is, for example, between 1000 and 20000 sccm, where the hydrogen (or deuterium) flow is more than 4000 sccm, a tungsten grain size is, for example, 40 nm or more.

In another embodiment, when tungsten halide flow of is, for example, less than 1000 sccm, a reducing agent flow is, for example, less than 1800 sccm, and hydrogen (or deuterium) flow is, for example, between 4000 and 12000 sccm, a tungsten grain size, for example, 40 nm or more is easier to obtain.

In an embodiment, after nucleation, at least one time of soak is further included, and nitrogen, hydrogen, deuterium or azane (NHx) are soaked. Nitrogen soak flow, hydrogen, deuterium or azane is, for example, less than 6000 sccm, and soak time is, for example, less than 200 s. The total soak flow (soak flow*soak time) is, for example, less than 20000 ml. When the total soak flow is less than 5000 ml, a tungsten grain size, for example, 70 nm or more is easier to obtain.

In an embodiment, times of nitrogen, hydrogen, deuterium or azane (NHx) soaked in soak is, for example, 1 to 3 times. When the times of the soak are less than 2 times, a tungsten grain size, for example, 70 nm or more is easier to obtain.

In an embodiment, when tungsten halide flow is, for example, less than 1000 sccm, hydrogen (or deuterium) flow is, for example, between 5000 and 12000 sccm. When the total soaking flow is less than 5000 ml, and times of soak is less than 1 time, a tungsten grain size, for example, 70 nm or more is easier to obtain.

For the bulk formation, in the bulk formation, a precursor of the bulk formation includes, for example, tungsten halide (such as tungsten fluoride), hydrogen (or deuterium), and a reducing agent. In the bulk formation, for example, inert gas including argon, helium, nitrogen, etc. may be added.

In an embodiment, when tungsten halide flow is, for example, less than 1000 sccm, and hydrogen (or deuterium) flow is, for example, between 1000 and 20000 sccm, preferably between 5000 and 12000 sccm, a tungsten grain size, for example, 70 nm or more is easier to obtain.

FIG. 2 is a flowchart of a manufacturing method a tungsten layer according to an embodiment of the disclosure. In an embodiment, the manufacturing method of the tungsten layer includes nucleation 200, soak 202, and bulk formation 204 performed. For example, in the nucleation 200, diborane (B₂H₆), hydrogen, argon, tungsten fluoride (WF₆), and argon are introduced in sequence. More detailed operations are, for example, that diborane and hydrogen are turned on and then are turned off after a predetermined time; argon is turned on and then is turned off after the predetermined time; tungsten fluoride is turned on and then is turned off after the predetermined time; argon is turned on and then is turned off after the predetermined time. The above steps are regarded as one cycle, and then a plurality of cycles (1 to 20 times) are performed to complete the nucleation.

In the soak 202, nitrogen is introduced. More detailed operations are, for example, that nitrogen is turned on and then is turned off after the predetermined time.

In the bulk formation 204, hydrogen, argon, tungsten fluoride, and argon are introduced in sequence. More detailed operations are, for example, that hydrogen is turned on and then is turned off after the predetermined time; argon is turned on and then is turned off after the predetermined time; tungsten fluoride is turned on and then is turned off after the predetermined time; argon is turned on and the is turned off after the predetermined time. The above steps are regarded as one cycle, and then a plurality of cycles (1 to 10000 times) are performed to complete the bulk formation.

In an embodiment, a manufacturing method of a metal layer 124 (tungsten layer) of the disclosure includes nucleation and 1 time or more of bulk formation performed in sequence. In an embodiment, a manufacturing method of a metal layer 124 (tungsten layer) of the disclosure includes nucleation and 2 to 3 times of bulk formation performed in sequence. In an embodiment, a manufacturing method of a metal layer 124 (tungsten layer) of the disclosure includes nucleation, soak, and 1 to 2 times of bulk formation performed in sequence. In an embodiment, a manufacturing method of a metal layer 124 (tungsten layer) of the disclosure includes nucleation, soak, bulk formation, the soak, and 1 to 2 times of the bulk formation performed in sequence. By the nucleation, the soak, and the bulk formation combined, the tungsten grain size, for example, 120 nm or more may also be obtained.

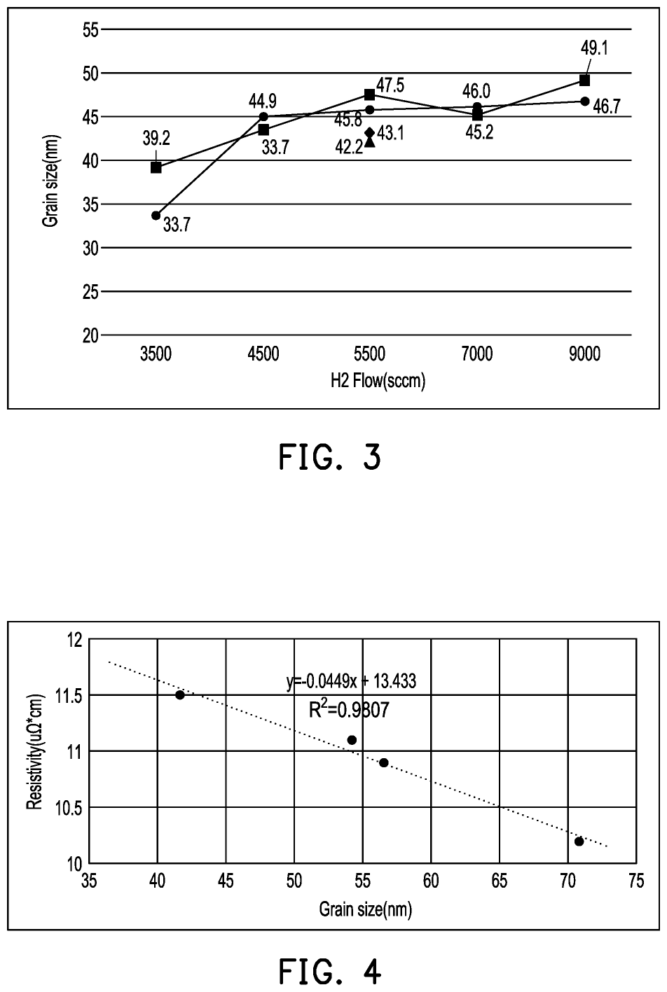

FIG. 3 is a graph illustrating a relationship between hydrogen flow and a tungsten grain size according to an embodiment of the disclosure. As shown in FIG. 3, three times of immersing by the same soak conditions of nitrogen are in the soak. In the subsequent bulk formation, the tungsten grain size increases from 33.7 nm (symbol: ●)/39.2 nm to 46.7 nm (symbol: ●)/49.1 nm as the hydrogen volume flow increases from 3500 sccm to 9000 sccm. Three times of immersing by different soak conditions of nitrogen are in the soak. In the subsequent bulk formation, the same hydrogen flow is used. The tungsten grain size in 1500 sccm nitrogen soak is 45.8 nm (soak time 15 s, symbol: ●)/47.5 nm (soak time 10 s, symbol: ^{▪}). The tungsten grain size in 3000 sccm nitrogen soak is 42.2 nm (soak time 15 s, symbol: ▴)/43.1 nm (soak time 10 s, symbol: ♦). The result shows that the nitrogen flow reduced in the soak enables the tungsten grain size to become larger.

FIG. 4 is a graph illustrating a relationship between a tungsten grain size and resistivity according to an embodiment of the disclosure. As shown in FIG. 4, the tungsten grain size has an inverse trend with the resistivity. Since a large grain has fewer grain boundaries, the resistivity of the large grain is lower than that of a small grain.

Conductivity: resistivity (uΩ*cm)=resistance*thickness.

The resistance and the thickness are the results of online measurement of the tungsten layer.

Table 1 discloses the experimental data of the tungsten grain size, fluorine content, and depth sidewall uniformity (U %) according to an embodiment of the disclosure.

Fluorine concentration: Secondary Ion Mass Spectrometer (SIMS) analysis, quantitative [F] concentration in the tungsten layer (atom/cm³).

Sidewall Uniformity: Scanning Electron Microscope (SEM) and Transmission Electron Microscope (TEM) analysis, U %=Standard Deviation/Average.

TABLE 1

| | | Depth sidewall uniformity (U %) | |
|---|---|---|---|
| Tungsten grain size | Fluorine content | Center | Edge |
| 42.00 | 5.26E+17 | 6.16 | 6.31 |
| 54.26 | 4.08E+17 | 10.2 | 9.0 |
| 70.75 | 3.58E+17 | 16.0 | 15.8 |

In the tungsten layer formed in the disclosure, as the tungsten grain size becomes larger, the fluorine content in the tungsten layer decreases. In the tungsten layer formed in the disclosure, as the tungsten grain size becomes larger, the depth sidewall uniformity becomes poor, but there is no problem of a tungsten seam under all conditions.

In the disclosure, the hydrogen flow increased in the nucleation and the bulk formation and the total nitrogen soak flow reduced in the soak are both beneficial to obtain a large tungsten grain size.

In a plurality of embodiments of the disclosure, the hydrogen flow increased in the nucleation and the bulk formation and the total nitrogen soak flow reduced in the soak are both beneficial to obtain the large tungsten grain size. In the tungsten layer formed, as the tungsten grain size becomes larger, the fluorine content in the tungsten layer decreases. The tungsten grain size in the tungsten layer is larger and has fewer grain boundaries, which reduces the resistivity of tungsten and impurity (fluorine) that is easily to damage a high-k dielectric constant material and a floating gate, narrows a threshold voltage (Vth) distribution, and improves reliability of the memory device.

What is claimed is:

1. A manufacturing method of a memory device, comprising:
providing a substrate;
forming a stacked structure on the substrate, wherein the stacked structure comprises a plurality of first material layers and a plurality of second material layers alternately stacked on each other;
patterning the stacked structure to form a first opening in the stacked structure;
forming a charge storage structure on a sidewall of the first opening;
forming a channel layer on the charge storage structure;
removing the plurality of second material layers to form a plurality of second openings; and
forming a tungsten layer in the plurality of second openings,
wherein the tungsten layer formed comprises:
performing a nucleation, a nucleation precursor in the nucleation comprising tungsten halide, hydrogen, and a reducing agent, and
after the nucleation, performing a bulk formation, and a bulk precursor in the bulk formation comprising tungsten halide, hydrogen, and a reducing agent,
in at least one of the nucleation and the bulk formation, hydrogen flow is between 1000 and 20000 sccm.

2. The manufacturing method of the memory device according to claim 1, further comprising performing at least one time of soak with at least one of nitrogen, hydrogen, deuterium and ammonia after the nucleation.

3. The manufacturing method of the memory device according to claim 1, further comprising performing a plurality of times of the bulk formation.

4. The manufacturing method of the memory device according to claim 3, comprising performing three times of the bulk formation.

5. The manufacturing method of the memory device according to claim 2, further comprising performing two times of the soak after the nucleation.

6. The manufacturing method of the memory device according to claim 1, further comprising forming a barrier layer is further comprised before forming the tungsten layer in the plurality of second openings.

7. The manufacturing method of the memory device according to claim 1, wherein in the nucleation, the hydrogen flow is 4000 sccm or more.

8. The manufacturing method of the memory device according to claim 1, wherein in the bulk formation, the hydrogen flow is 5000 sccm or more.

9. The manufacturing method of the memory device according to claim 2, wherein in the soak, a nitrogen flow is between 100 and 6000 sccm.

10. A manufacturing method of a tungsten layer, comprising:
performing nucleation, and a nucleation precursor in the nucleation comprising tungsten halide, hydrogen, and a reducing agent; and
performing a plurality of times of bulk formation, and a bulk precursor in the bulk formation comprising tungsten halide, hydrogen, and a reducing agent, wherein in at least one of the nucleation and the bulk formation, hydrogen flow is between 1000 and 20000 sccm.

11. The manufacturing method of the tungsten layer according to claim 10, further comprising performing at least one time of soak with at least one of nitrogen, hydrogen, deuterium and ammonia after the nucleation after the nucleation.

12. The manufacturing method of the tungsten layer according to claim 10, further comprising performing three times of the bulk formation.

13. The manufacturing method of the tungsten layer according to claim 11, further comprising performing two times of the soak after the nucleation.

14. The manufacturing method of the tungsten layer according to claim 10, wherein in the nucleation, the hydrogen flow is 4000 sccm or more.

15. The manufacturing method of the tungsten layer according to claim 10, wherein in the bulk formation, the hydrogen flow is 5000 sccm or more.

16. The manufacturing method of the tungsten layer according to claim 11, wherein in the soak, nitrogen flow is between 100 and 6000 sccm.
